(19) United States
(12) Patent Application Publication
(10) Pub. No.: US 2006/0104379 A1
(43) Pub. Date: May 18, 2006

(54) Technique to increase a code rate in a MIMO system using virtual channels

(76) Inventors: Qinghua Li, Sunnyvale, CA (US); Ada Shuk Yan Poon, San Leandro, CA (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/990,260

(22) Filed: Nov. 15, 2004

(51) Int. Cl. H04L 1/02; H03M 13/03

(52) U.S. Cl. 375/267; 714/790

(57) ABSTRACT

Various techniques and embodiments are described to increase a code rate in a MIMO system using one or more virtual channels.

### BACKGROUND INFORMATION

Communication systems include a number of parameters which need to be established, such as a data rate, a modulation scheme, a code rate, and the type of puncturing, if any, that will be used. Some communication systems may include certain features or parameters that may be adapted based on changing conditions. For example, some systems allow a data transmission rate to be adjusted based upon a detected transmission condition or channel quality.

### BRIEF DESCRIPTION OF THE DRAWINGS

FIG. 1 is a diagram illustrating an example of a wireless communication system in accordance with one embodiment of the invention.

FIG. 2 is a block diagram of a wireless transmitter and a wireless receiver according to an example embodiment.

FIG. 3 is a diagram illustrating operation of the code bit distributor shown in FIG. 2 according to an example embodiment.

FIG. 4 is a block diagram of a wireless transmitter according to another example embodiment.

FIG. 5 is a block diagram of a wireless transmitter according to yet another example embodiment.

FIG. 6 is a block diagram of a wireless transmitter according to another example embodiment.

FIG. 7 is a block diagram of a wireless transmitter according to yet another example embodiment.

FIG. 8 is a block diagram of a wireless transmitter according to yet another example embodiment.

FIG. 9 is a block diagram of a wireless transmitter according to yet another example embodiment.

FIG. 10 is a block diagram of a wireless transmitter according to yet another example embodiment.

### DETAILED DESCRIPTION

In the detailed description, numerous specific details are set forth in order to provide a thorough understanding of the embodiments of the invention. It will be understood by those skilled in the art, however, that embodiments of the invention may be practiced without these specific details. In other instances, well-known methods, procedures and techniques have not been described in detail so as not to obscure the foregoing embodiments.

Some portions of the detailed description that follows are presented in terms of algorithms and symbolic representations of operations on data bits or binary digital signals within a computer memory. These algorithmic descriptions and representations may be the techniques used by those skilled in the data processing arts to convey the substance of their work to others skilled in the art.

An algorithm is here, and generally, considered to be a self-consistent sequence of acts or operations leading to a desired result. These include physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers or the like. It should be understood, however, that all of these and similar terms are to be associated with the appropriate physical quantities and are merely convenient labels applied to these quantities.

Unless specifically stated otherwise, as apparent from the following discussions, it is appreciated that throughout the specification discussions utilizing terms such as processing, computing, calculating, determining, or the like, refer to the action or processes of a computer or computing system, or similar electronic computing device, that manipulate or transform data represented as physical, such as electronic, quantities within the registers or memories of the computing system into other data similarly represented as physical quantities within the memories, registers or other such information storage, transmission or display devices of the computing system.

Embodiments of the present invention may include apparatuses for performing the operations herein. This apparatus may be specially constructed for the desired purposes, or it may comprise a general purpose computing device selectively activated or reconfigured by a program stored in the device. Such a program may be stored on a storage medium, such as, but is not limited to, any type of disk including floppy disks, optical disks, CD-ROMs, magnetic-optical disks, read-only memories (ROMs), random access memories (RAMs), electrically programmable read-only memories (EPROMs), electrically erasable and programmable read only memories (EEPROMs), flash memory, magnetic or optical cards, or any other type of media suitable for storing electronic instructions, and capable of being coupled to a system bus for a computing device.

The processes and displays presented herein are not inherently related to any particular computing device or other apparatus. Various general purpose systems may be used with programs in accordance with the teachings herein, or it may prove convenient to construct a more specialized apparatus to perform the desired method. The desired structure for a variety of these systems will appear from the description below. In addition, embodiments of the present invention are not described with reference to any particular programming language. It will be appreciated that a variety of programming languages may be used to implement the teachings of the invention as described herein.

In the following description and claims, the terms coupled and connected, along with their derivatives, may be used. In particular embodiments, connected may be used to indicate that two or more elements are in direct physical or electrical contact with each other. Coupled may mean that two or more elements are in direct physical or electrical contact. However, coupled may also mean that two or more elements may not be in direct contact with each other, but yet may still cooperate or interact with each other.

It is worthy to note that any reference in the specification to “one embodiment” or “an embodiment” means in this context that a particular feature, structure, or characteristic described in connection with the embodiment may be included in at least one embodiment of the invention. The appearances of the phrase “in one embodiment” or “an embodiment” in various places in the specification do not necessarily refer to the same embodiment, but may be referring to different embodiments.

It should be understood that embodiments of the present invention may be used in a variety of applications. Although the present invention is not limited in this respect, the circuits disclosed herein may be used in many apparatuses such as in the transmitters and receivers of a radio system. Radio systems intended to be included within the scope of the present invention include, by way of example only, wireless local area networks (WLAN) devices, wireless metropolitan area networks (WMAN) devices, and wireless wide area network (WWAN) devices including wireless network interface devices and network interface cards (NICs), base stations, access points (APs), gateways, bridges, hubs, cellular radiotelephone communication systems, satellite communication systems, two-way radio communication systems, one-way pagers, two-way pagers, personal communication systems (PCS), personal computers (PCs), personal digital assistants (PDAs), and the like, although the scope of the invention is not limited in this respect.

As used herein, the term packet may include a unit of data that may be routed or transmitted between nodes or stations or across a network. As used herein, the term packet may include frames, protocol data units or other units of data. A packet may include a group of bits, which may include one or more address fields, control fields and data, for example. A data block may be any unit of data or information bits.

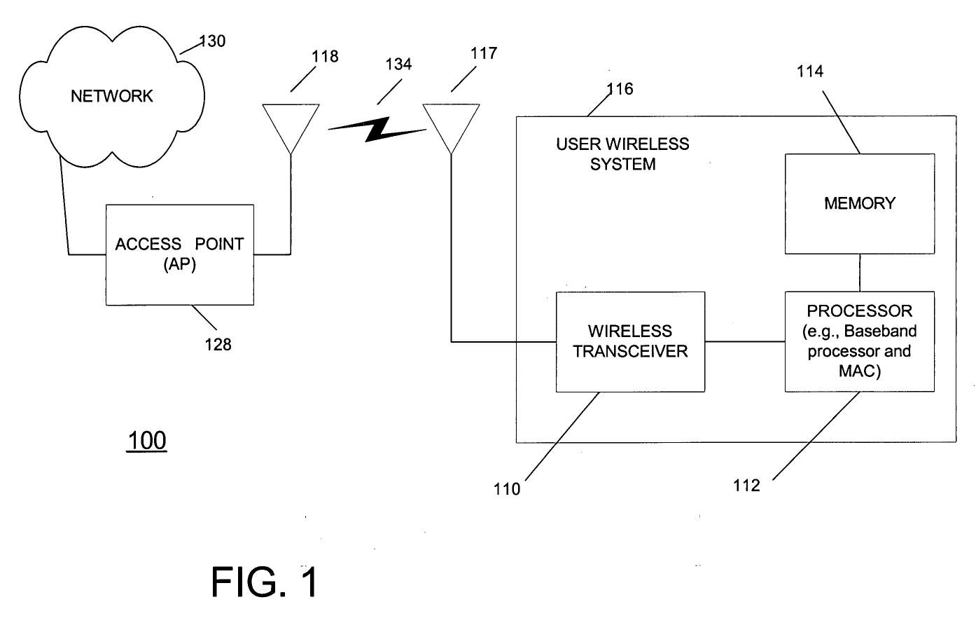

Referring to the Figures in which like numerals indicate like elements, FIG. 1 is a diagram illustrating an example of a wireless communication system in accordance with one embodiment of the invention. In the communications system 100 shown in FIG. 1, a user wireless system 116 may include a wireless transceiver 110 coupled to an antenna 117 and to a processor 112. Processor 112 in one embodiment may comprise a single processor, or alternatively may comprise a baseband processor and an applications processor, although the scope of the invention is not limited in this respect. According to one embodiment, processor 112 may include a baseband processor and Medium Access Control (MAC).

Processor 112 may couple to a memory 114 which may include volatile memory such as DRAM, non-volatile memory such as flash memory, or alternatively may include other types of storage such as a hard disk drive, although the scope of the invention is not limited in this respect. Some portion or all of memory 114 may be included on the same integrated circuit as processor 112, or alternatively some portion or all of memory 114 may be disposed on an integrated circuit or other medium, for example a hard disk drive, that is external to the integrated circuit of processor 112, although the scope of the invention is not limited in this respect. According to one embodiment, software may be provided in memory 114 to be executed by processor 112 to allow wireless system 116 to perform a variety of tasks, some of which may be described herein.

Wireless system 116 may communicate with an access point (AP) 128 (or a base station or other wireless system) via wireless communication link 134, where access point 128 may include at least one antenna 118. Antennas 117 and 118 may each be, for example, a directional antenna or an omni directional antenna, may be a single element antenna or a multi-element antenna system or arrayed antenna, and the like, although the invention is not limited thereto. Although not shown in FIG. 1, AP 128 may, for example, include a structure that is similar to wireless system 116, including a wireless transceiver, a processor, a memory, and software provided in memory to allow AP 128 to perform a variety of functions. In an example embodiment, wireless system 116 and AP 128 may be considered to be stations in a wireless communication system, such as a WLAN system.

Access point 128 may be coupled to network 130 so that wireless system 116 may communicate with network 130, including devices coupled to network 130, by communicating with access point 128 via wireless communication link 134. Network 130 may include a public network such as a telephone network or the Internet, or alternatively network 130 may include a private network such as an intranet, or a combination of a public and a private network, although the scope of the invention is not limited in this respect.

Communication between wireless system 116 and access point 128 may be implemented via a wireless local area network (WLAN), for example a network which may be compliant with an Institute of Electrical and Electronics Engineers (IEEE) standard such as IEEE 802.11a, IEEE 802.11b, IEEE 802.11g, IEEE 802.11n, IEEE 802.15, IEEE 802.16 and so on, although the scope of the invention is not limited in this respect.

In another embodiment, communication between wireless system 116 and access point 128 may be implemented via a cellular communication network compliant with a 3GPP standard, although the scope of the invention is not limited in this respect.

One or more aspects of the invention may be applied to single carrier systems where information may be transmitted over a single carrier. Alternatively, one or more aspects of the invention may be applied to multicarrier systems, such as an OFDM (Orthogonal Frequency Division Multiplexing) system for example, where information may be transmitted over multiple carriers or subcarriers, although the invention is not limited in this regard. According to an example embodiment, one or more aspects of the invention may apply to multiple-input, multiple output wireless systems known as MIMO. MIMO systems may transmit and receive information using two or more antennas to take advantage of spatial diversity (e.g., using an antenna array that includes 2 or more antenna elements).

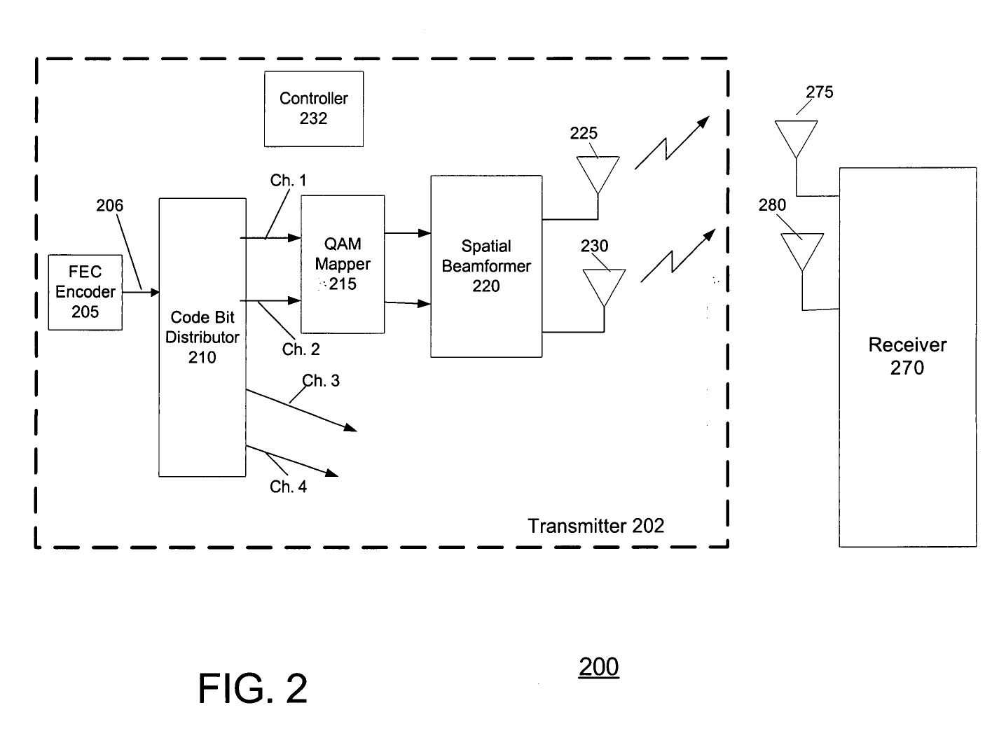

FIG. 2 is a block diagram of a wireless transmitter 202 to transmit information, and a wireless receiver 270 to receive information, according to an example embodiment. Transmitter 202 and receiver 270 may be in wireless communication. Wireless transmitter 202 may be part of a first wireless transceiver (including both a wireless transmitter and receiver). Likewise, wireless receiver 270 may be part of a second wireless transceiver (including both a wireless transmitter and receiver).

As shown in FIG. 2, in an example embodiment, wireless transmitter 202 may include an encoder 205 to encode data bits, a code bit distributor 210 to distribute code bits to a plurality of spatial channels, a QAM mapper 215 to map groups of code bits to modulation symbols for one or more of the spatial channels, and a spatial beamformer 220. In an example embodiment, a spatial channel may be formed by multiple transmit antennas and multiple receive antennas in spatial multiplexing, although the invention is not limited thereto. In spatial multiplexing, according to an example embodiment, both the transmit and receive sides may have multiple antennas, and multiple data streams may be sent and received through multiple spatial channels simultaneously, although the invention is not limited thereto. Other types of spatial channels may be used as well. In one example embodiment, each spatial channel may be transmitted via a separate antenna, although the invention is not limited thereto. However, more commonly, the spatial channels may be passed through a beamforming matrix such that some combination of the group of spatial channels may be transmitted via each antenna, although the invention is not limited thereto.

Antennas 225 and 230 are coupled to spatial beamformer 220 to receive and radiate signals. In an example embodiment, one or more of the FEC encoder 205, code bit distributor 210, QAM mapper 215 and spatial beamformer 220 may operate under control of controller 232, although the invention is not limited thereto.

Referring to FIG. 2, encoder 205 may comprise a forward error correction (FEC) encoder, for example. Coding (or encoding) of data may, for example, involve coding received data bits using a coding technique (such as convolutional coding, block coding, etc.) to produce coded bits or code bits. FEC encoder 205 may encode data bits at a specific code rate. A code rate may be considered to be a ratio of data bits/code bits. For example, if FEC encoder 205 outputs 10 code bits for every 5 data bits, the code rate may be considered to be: code rate=5/10, or 1/2. A code rate output from FEC encoder 205 may also be referred to as a mother code rate or original or nominal code rate. In an example embodiment, FEC encoder 205 may encode data bits at one code rate, or encode data bits at one selected code rate of a plurality of possible code rates. FEC encoder 205 may have a maximum code rate, of 3/4 for example, although the invention is not limited thereto.

As described below, according to an example embodiment, an original code rate may be increased by assigning one or more code bits to one or more virtual channels, although the invention is not limited thereto. In an example embodiment, a virtual channel may be a dummy (or fake) channel which is not transmitted, or has one or more bits thereon that are punctured or transmitted at zero or near zero power, etc., although the invention is not limited thereto. The number of virtual channels may be zero or more (e.g., 0, 1, 2, 3, 4, . . . ), and the number of virtual channels may be variable. For example, the number of virtual channels used by a transmitter may be selected, for example, based on a channel condition(s), such as signal to noise ratio, error rate, received signal strength, etc. For example, for channel conditions above a first predetermined threshold, a transmitter may select, say, one virtual channel to be used to increase a code rate for the transmitter (as seen by the receiver). For channel condition above a second predetermined channel condition, the transmitter may select to use two virtual channels, to increase the code rate even higher, although the invention is not limited thereto.

Referring again to FIG. 2, code bit distributor 210 may be coupled to the output of FEC encoder 205. Code bit distributor 210 may demultiplex or distribute or assign the received code bits to one or more of a plurality of spatial channels. For example, in a simple embodiment, every fourth code bit may be allocated across each of channels 1-4, in a round-robin fashion, although the invention is not limited thereto. Many other techniques may be used to assign or distribute code bits to a plurality of channels, including assigning an unequal number of bits across each of the channels.

In an example embodiment, code bit distributor 210 may distribute or assign each of the code bits to one of the spatial channels, including, for example, spatial channels 1-4 (shown as outputs from code bit distributor 210). According to an example embodiment, code bit distributor 210 may assign each code bit to a real spatial channel or to a virtual (or dummy) spatial channel. The code bits assigned to a real channel may be transmitted, while bits assigned to a virtual channel may typically be discarded (e.g., may not be transmitted or transmitted at zero power, or otherwise punctured), according to an example embodiment, although the invention is not limited thereto. Puncturing may involve, for example, discarding or dropping (e.g., not transmitting) certain code bits, for example, in order to increase the code rate for the transmitter.

According to an example embodiment, channels 1 and 2 may be real spatial channels, while channels 3 and 4 may be virtual spatial channels. Thus, this system may be considered to be a virtual 4×4 MIMO system (e.g. including the two real spatial channels plus the two virtual spatial channels). In an example embodiment, the notation n×m may denote that there are n transmit antennas and m receive antennas in the system, and the maximum number of spatial channels may be the minimum number between n and m, although the invention is not limited thereto. Although, the system may be considered a real 2×2 MIMO system because there are only 2 real antennas on both transmit and receive sides (and only 2 real antennas).

According to an example embodiment, the transmitter may notify the receiver that the transmitter will send 4 data streams using 4 spatial channels while it actually only sends 2 data streams using 2 available spatial channels. The receiver may first estimate from the received signals the number of actual data streams (or channels) that are sent, and may then demodulate them.

In another example embodiment, the transmitter and receiver may communicate according to a predefined standard or protocol in which a certain number (e.g., which may be variable) of spatial channels are supported. For example, a standard or protocol may support 4 spatial channels, or up to 4 spatial channels, although the invention is not limited thereto.

In an example embodiment, the receiver may assume that these spatial channels are real channels. In an example embodiment, the concept of a transmitter using one or more virtual channels may not be provided or explicitly supported in the standard or protocol (e.g., may not be known by the receiver). For example, a transmitter may use 4 spatial channels, including 2 real channels and 2 virtual channels, although a standard compliant receiver may not know of the virtual channels, although the invention is not limited thereto. In order to increase an effective code rate, the transmitter may deliberately claim to be using a legitimate transmission mode in the standard, which sends 4 real spatial channels, while it may actually send only 2 real channels and discards or punctures the other 2 channels (in virtual channels). In this manner, a transmitter may effectively increase the code rate, while using the pre-existing code rates (e.g., not requiring the higher code rate to be explicitly added to the standard), although the invention is not limited to such as situation.

Therefore, an advantage of using such a fake (virtual) 4-spatial- channel mode (e.g., with 2 virtual channels and 2 real channels at the transmitter) is that this 4-spatial-channel mode may be already defined in a standard protocol between transmitter and receiver and may be utilized to increase the effective code rate without necessarily defining additional code rates in the standard, although the invention is not limited thereto. Many other embodiments are possible, and the invention is not limited by the examples described above.

For example, alternatively, the use of one or more virtual channels (e.g., a virtual channel mode) may be explicitly supported by a particular protocol or standard, e.g., as between a transmitter and a receiver, although the invention is not limited thereto. These are merely some additional embodiments, and many other implementations are possible and within the scope of the invention.

In an example embodiment, a transmitter of a MIMO system may include L spatial channels, and may include K real channels with non-zero power loading, and may include L-K virtual (or dummy) channels (with K<L) with zero power loading (e.g., code bits of such virtual channels may not be transmitted, or may be discarded or may otherwise be punctured). In order to increase the code rate, one or more virtual channels may be provided (along with one or more real channels). The transmitter may assign code bits to the real channels (e.g., channels 1 and 2) and may assign code bits to one or more virtual channels (e.g., channels 3 and 4). By assigning one or more code bits to one or more virtual channels, the effective code rate (e.g., as seen by the receiver) may be increased since the code bits assigned to the virtual channels may be discarded, according to an example embodiment.

Referring to FIG. 2, QAM mapper 215 is coupled to the output of code bit distributor 210. In the example of FIG. 2, QAM mapper receives the code bits output for real channels 1 and 2. QAM mapper 215 may map groups of code bits to a corresponding modulation symbol, for each spatial channel input to QAM mapper 215 (e.g., for the real channels 1 and 2). In an example embodiment, QAM mapper 215 (and other QAM mappers disclosed herein) may map code bits to a modulation symbol for a specific physical OFDM subcarrier. QAM mapper 215 may output symbols based on the input code bits for each input spatial channel. Data throughput may be impacted by both the code rate and the modulation scheme used for symbols.

A variety of different modulation schemes may be used. For example the following modulation schemes may be used: binary phase-shift keying (BPSK), quadrature phase shift keying (QPSK), Quadrature Amplitude Modulation (QAM) such as 16-QAM (16 different symbols), 64-QAM (64 different symbols), 256 QAM, etc., although the invention is not limited thereto. Other modulation schemes may be used. A different modulation scheme may be selected and used for each different channel, although the invention is not limited thereto. For example, if 64-QAM is selected for channel 1, each group of 6 code bits provided over channel 1 may be mapped to a corresponding 64-QAM symbol. And if 16-QAM is selected for channel 2, for example, then each group of 4 code bits received on channel 2 may be mapped to a 1 6-QAM modulation symbol (constellation symbol).

According to another example embodiment, a different code rate and modulation scheme may be used for each spatial channel, e.g., based upon a measured or received channel quality parameter such as SNR, received signal strength, etc., or other value or measurement. The code rate and modulation scheme for each channel may, for example, be selected by controller 232 based on such parameters or measurements. Controller 232 may provide control signals to code bit distributor 210 to assign or distribute certain code bits (or a specified number of code bits) to real channels and to distribute or assign other code bits to virtual channels in order to achieve a desired code rate for that channel. In this manner, the number of code bits assigned to virtual channels may be adjusted under control of controller 232 to vary the code rate for each real spatial channel. Likewise, controller 232 may provide control signals to QAM mapper 215 to select a modulation scheme for each spatial channel (e.g., for each real channel) based on a measured or received channel condition, or other measurements or values. In an example embodiment, higher code rates and higher modulation schemes may be used for spatial channels having higher quality signals (e.g., higher SNR or greater received signal strength) in order to improve throughput on such spatial channels, although the invention is not limited thereto.

Spatial beamformer 220 (FIG. 2) is coupled to the output of QAM mapper 215. Spatial beamformer 220 may adjust the amplitude (or gain) and phase for each of the antennas 225 and 230 to form or steer the electromagnetic beam (i.e., to provide the desired peaks and nulls of the electromagnetic beam) that is radiated by antennas 225 and 230. Beamforming may be done, for example, to improve signal reception at receiver 270. The beamforming may be accomplished by applying (or multiplying) a complex weight (e.g., including amplitude and phase) to the transmit signal. In this case, the transmit signal may be the QAM symbols for the real spatial channels (e.g., channels 1 and 2) output by QAM mapper 215, which may be multiplied by the complex weights, according to an example embodiment, although the invention is not limited thereto. Other blocks (not shown) may also be provided within transmitter 220. In an example embodiment, spatial beamformer 220 may include a processor or a digital signal processor to generate and apply (e.g., multiply) the complex weights. In an example embodiment, the spatial beamformer 220 may be an adaptive spatial beamformer in which the complex weights may be adapted on the fly to improve the quality of the received signals, although the invention is not limited thereto.

Referring to FIG. 2 again, according to an example embodiment, receiver 270 may receive and demodulate signals associated with the two real channels (channels 1 and 2) via antennas 275 and 280. According to an example embodiment, receiver 270 may insert zeros at an input to a channel decoder (not shown) for the missing code bits assigned to the virtual channels, since these missing code bits may have been discarded or dropped at the transmitter as part of the virtual spatial channels, although the invention is not limited thereto. In an example embodiment, as part of the coding process, redundancy information provided within other code bits received by receiver 270 may be used to generate the missing code bits that were assigned to the virtual channels, although the invention is not limited thereto. Other techniques may be used to handle the missing code bits that were assigned to the virtual channels at the transmitter 202. For example, receiver 270 may assign a low confidence or zero confidence level to the missing code bits, e.g., as part of a Viterbi decoding algorithm, although the invention is not limited thereto.

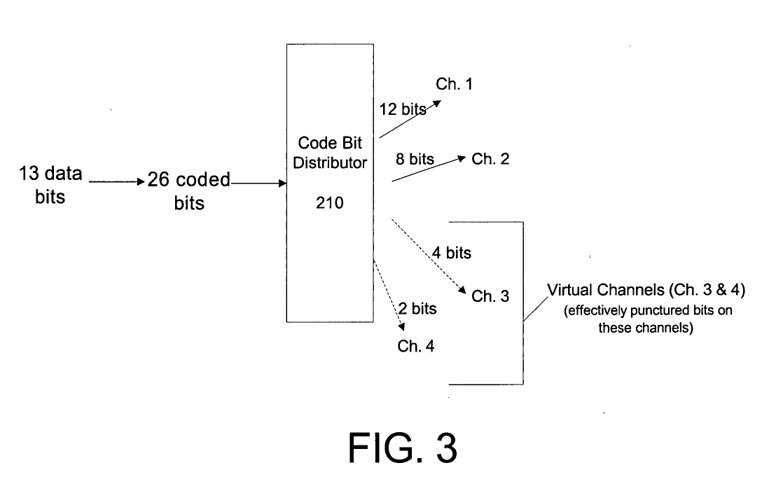

FIG. 3 is a diagram illustrating operation of code bit distributor 210 (FIG. 2) according to an example embodiment. As shown in the example of FIG. 3, 13 data bits may be coded by FEC encoder 205 as 26 code bits, to provide an original code rate or mother code rate of 1/2. The 26 code bits are distributed or assigned by code bit distributor 210 to the 4 spatial channels. In an example embodiment, 12 code bits are assigned to channel 1 (a real channel), 8 code bits are assigned to channel 2 (a real channel), 4 code bits are assigned to channel 3 (a virtual channel) and 2 code bits are assigned to channel 4 (a virtual channel), although the invention is not limited thereto. As can be seen in FIG. 2, the code bits in channels 1 and 2 are sent on to QAM mapper 215 for mapping and are eventually transmitted, while the code bits assigned to (virtual) channels 3 and 4 may be discarded, and thus, may be effectively punctured. Therefore, in this example, the code rate is effectively increased from 1/2 to 13/20 due to the 6 bits that are discarded via virtual channels 3 and 4.

Table 1 below illustrates some example modulation schemes and amplitude or gain applied to each of the spatial channels. In this example embodiment, zero power is applied to the virtual channels 3 and 4, thereby discarding or not transmitting the code bits on those channels, although the invention is not limited thereto. Also, in this example, 64-QAM may be used as the modulation scheme for channel 1 (e.g., due to a higher quality channel or higher SNR on channel 1), 16-QAM may be used for channel 2, QPSK may be used for virtual channel 3, and BPSK may be used for virtual channel 4. This is simply an example, and the invention is not limited thereto. Many different combinations of gain, modulation schemes, etc. may be used for different channels. The code bits for the virtual spatial channels 3 and 4 may not necessarily be mapped to modulation symbols since these code bits may preferably be discarded or punctured to increase the code rate, according to an example embodiment. In addition, in this example, the 12 code bits assigned to channel 1 are mapped to two 64-QAM modulation symbols (6 code bits per symbol), while the 8 code bits assigned to channel 2 may be mapped to two 16-QAM symbols (4 bits per symbol).

TABLE 1
Example of puncturing using virtual channels.

| | |
|---|---|
| Nominal code rate of virtual 4 × 4 | 1/2 |
| Constellation for channel 1 | 64-QAM with power loading 0.8 |
| Constellation for channel 2 | 16-QAM with power loading 0.2 |
| Constellation for virtual channel 3 | QPSK with no power |
| Constellation for virtual channel 4 | BPSK with no power |
| Effective code rate real 2 × 2 | 13/20 |

In an example embodiment, the transmitter may select the code bits or the number of code bits that may be assigned to virtual spatial channels (such code bits may typically be discarded or effectively punctured) in advance, or may make this decision dynamically (e.g., on the fly) based on, for example, a measured channel quality such as a signal to noise ratio (SNR), received signal strength or other quality parameter. For example, in another embodiment, the 4 bits previously assigned to channel 3 may be transmitted via real channel 2, while the 8 bits previously assigned to channel 2 may be assigned to the virtual channel 3 (effectively punctured), providing a slightly higher code rate of 13/16 in this example, due to puncturing of 10 bits versus 6 bits.

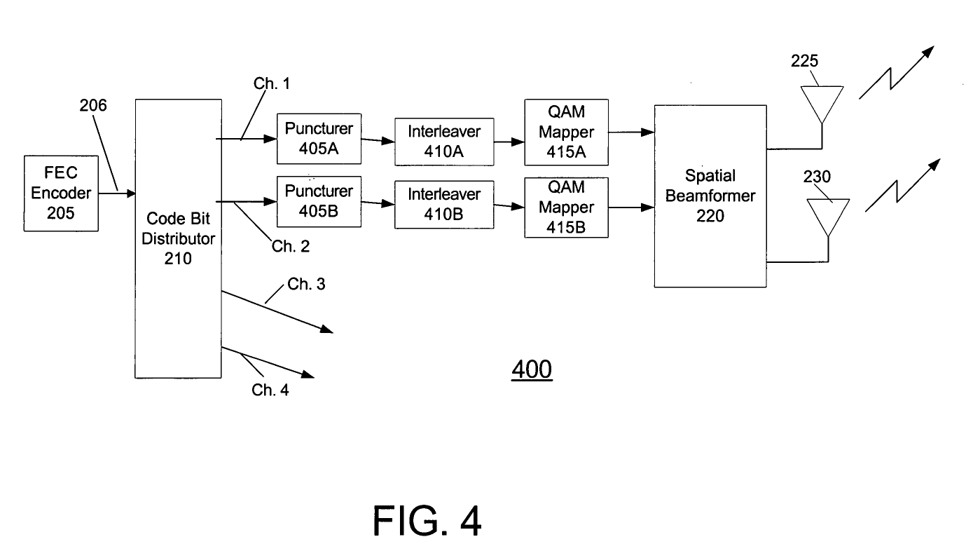

FIG. 4 is a block diagram of a wireless transmitter according to another example embodiment. Transmitter 400 (FIG. 4) is essentially the same as the transmitter 202 (FIG. 2), except for the presence of puncturers 405A and 405B and interleavers 410A and 410B. Puncturers 405A and 405B are coupled to channel 1 and channel 2, respectively, output from code bit distributor 210, to selectively puncture one or more bits in the code bit stream output in the respective spatial channel. This additional per channel puncturing (e.g., in addition to the use of virtual channels) may allow further increases or variations to the transmitter code rate.

Referring again to FIG. 4, interleavers 410A and 410B are coupled to the outputs of puncturers 405A and 405B, respectively. Interleavers 410A and 410B may interleave or change the order of the code bits input to QAM mappers 415A and 415B, respectively. Alternatively, a single interleaver 410 (coupled to both puncturers and to both QAM mappers) may be provided to also allow interleaving of code bits between different spatial channels (in addition to interleaving of code bits within a spatial channel). In an example embodiment, the interleaver 410 (and the other interleavers disclosed herein) may perform a permutation on the input bit sequence, which may change the order between the input bit sequence and the output bit sequence (changes the order of bits from the input of the interleaver to its output). For example, an input bit sequence b1, b2, b3, b4, b5, b6 may be changed to b6, b1, b2, b3, b4, b5. In an example embodiment, a block interleaver may be used to change the order of the bits, which for example, may write a group of bits into rows of a matrix and then read the bits out by the columns to change the order of the block of bits. At the receiver, this operation may be reversed to place the bits back in their original order. Other types of interleavers may be used, such as a convolutional interleaver and the like. The example interleavers described above are provided only as examples, and the invention is not limited thereto.

QAM mapper 415 may map groups of code bits to modulation symbols for one or more of the spatial channels, and in an example embodiment, may map code bits to symbols for a specific or selected physical OFDM subcarrier, although the invention is not limited thereto. Although not shown in FIG. 4, transmitter 400 may include a controller, such as controller 232 of FIG. 2, to control the operation of one or more of: FEC encoder, 205, code bit distributor 210, puncturers 405, interleavers 410, QAM mappers 415, and spatial beamformer 220, although the invention is not limited thereto.

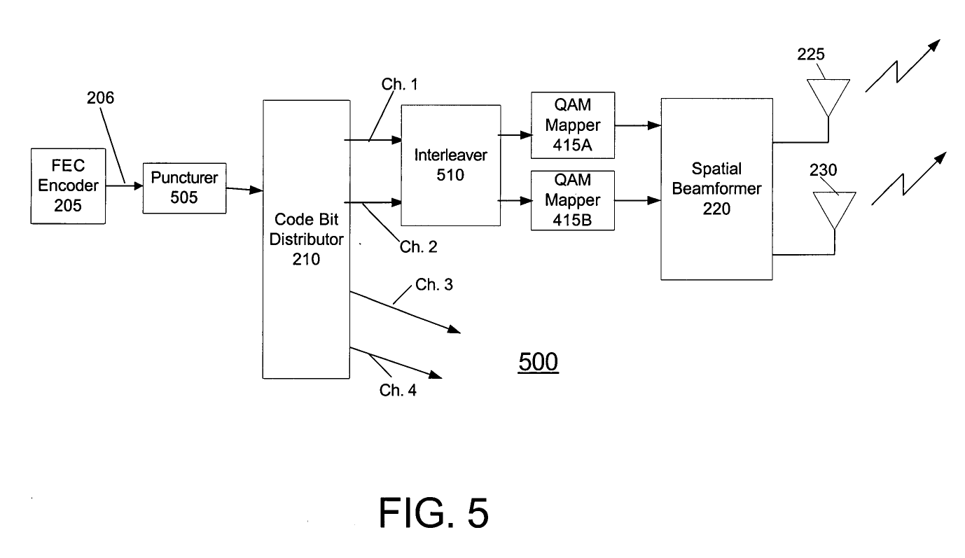

FIG. 5 is a block diagram of a wireless transmitter according to yet another example embodiment. The example transmitter 500 shown in FIG. 5 is similar to the transmitter 400 in FIG. 4. However, transmitter 500 includes a puncturer 505 provided between the FEC encoder 205 and the code bit distributor 210. Puncturer 505 may puncture (or discard or drop) one or more bits output from FEC encoder, and may also be used to alter or increase the code rate output from encoder 205. An additional opportunity (in addition to puncturer 505) to increase the code rate may be provided by the use of virtual channels via the code bit distributor 210, as explained above. Transmitter 500 also includes an interleaver 510 coupled to a plurality of real spatial channels output from the code bit distributor and to QAM mappers 415A and 415B. The other aspects of transmitter 500 are essentially the same as transmitter 400.

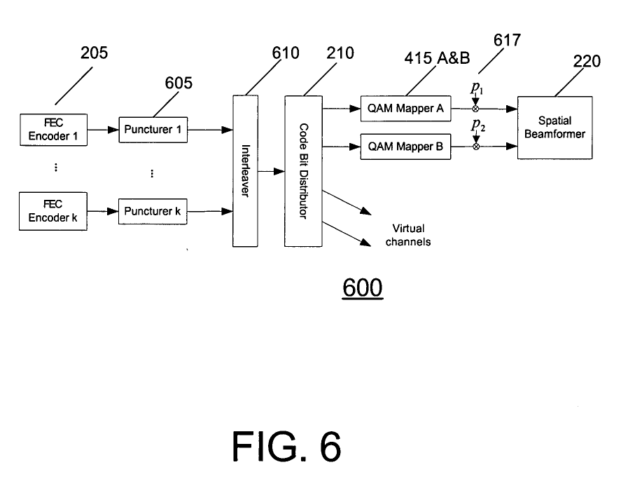

FIG. 6 is a block diagram of a wireless transmitter according to another example embodiment. Transmitter 600 may be very similar to the transmitters described above, with some slight variations. Transmitter 600 may include one or more FEC encoders 205 to encode data bits, one or more puncturers 605 to puncture code bits, an interleaver 610 to interleave code bits, a code bit distributor 210, and QAM mappers 415A and 415B (e.g., for spatial channels A and B, respectively). Transmitter 600 may include a power adjustment 617 to apply variable power loading for each spatial channel (e.g., under control of a controller not shown), and a spatial beamformer 220. Alternatively, power adjustment 617 may provided within beamformer 220.

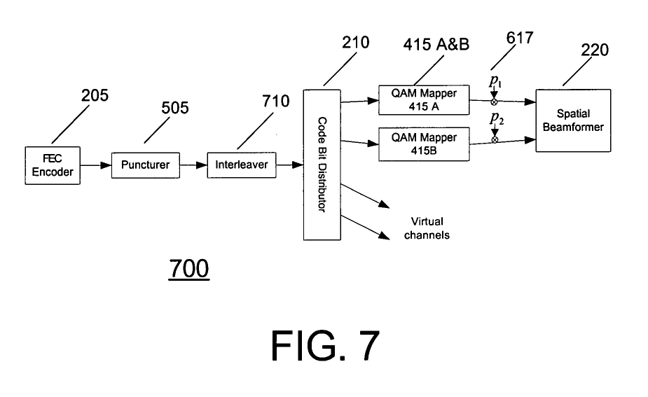

FIG. 7 is a block diagram of a wireless transmitter according to yet another example embodiment. Transmitter 700 may be very similar to the transmitters described above, with some slight variations. Transmitter 700 may include one or more FEC encoders 205 to encode data bits, one or more puncturers 505 to puncture code bits, an interleaver 710 to interleave code bits, a code bit distributor 210, and QAM mappers 415A and 415B (e.g., for spatial channels A and B, respectively). Transmitter 700 may include a power adjustment 617 to apply variable power loading for each spatial channel (e.g., under control of a controller not shown), and a spatial beamformer 220. Alternatively, power adjustment 617 may provided within beamformer 220.

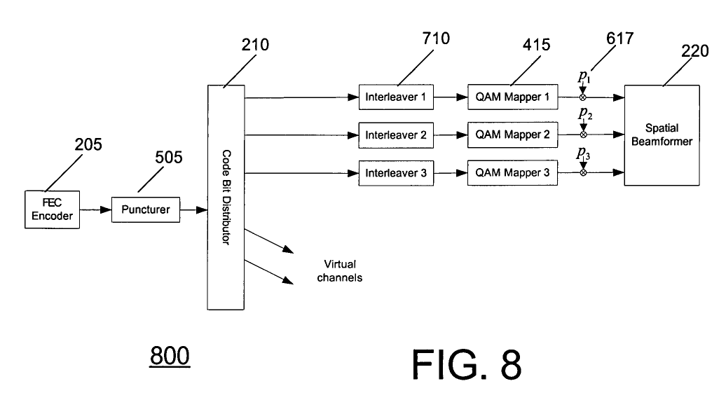

FIG. 8 is a block diagram of a wireless transmitter according to yet another example embodiment. Transmitter 800 may be very similar to the transmitters described above, with some slight variations. Transmitter 800 may include one or more FEC encoders 205 to encode data bits to code bits, one or more puncturers 505 to puncture code bits, and a code bit distributor 210 to distribute code bits to one or more spatial channels (including real and virtual channels). Code bit distributor 210 may select a variable number of virtual channels to use, e.g., based on a channel condition. Code bits may be allocated to either a real channel or to a virtual channel (if a virtual channel has been selected by the transmitter for use). Interleavers 710 are provided to interleave code bits, e.g., one interleaver for each real spatial channel (interleaver 1, 2 and 3). In an example embodiment, the interleavers may be different, which generates a different output order for each interleaver. QAM mappers 415 are provided for each spatial channel (e.g., QAM mappers 1, 2 and 3). Transmitter 800 may include a power adjustment 617 to apply variable power loading for each spatial channel (e.g., under control of a controller not shown), and a spatial beamformer 220. Alternatively, power adjustment 617 may provided within beamformer 220.

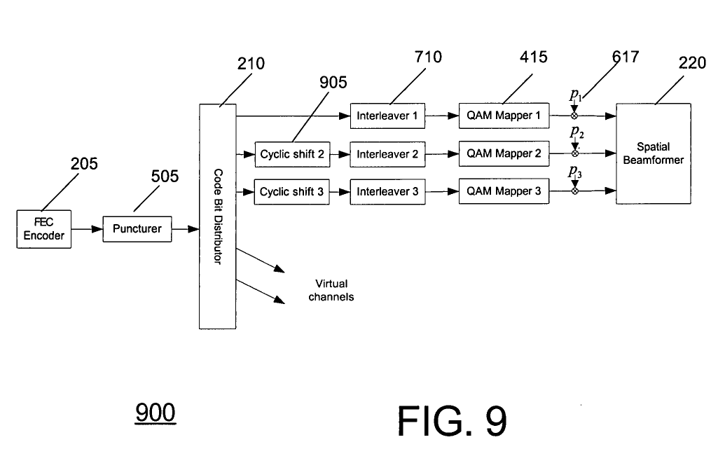

FIG. 9 is a block diagram of a wireless transmitter according to yet another example embodiment. Transmitter 900 may be very similar to the transmitter 800 shown in FIG. 8, with some differences described below. Cyclic shifters 905 may be provided for one or more real spatial channels. A cyclic shifter may shift a group of bits a certain number of positions, and then output them. In an example embodiment, the cyclic shift may be considered to be a rotational shift, although the invention is not limited thereto. For example, a one-step cyclic shift for the input bit sequence b1, b2, b3, b4, b5 may result in the output sequence b5, b1, b2, b3, b4, b6. A two step cyclic shift on the input sequence b1, b2, b3, b4, b5, b6 may result in the output sequence b5, b6, b1, b2, b3, b4, although the invention is not limited thereto. Other types of cyclic shift may be used. As can be seen, in the example embodiment of FIG. 9, code bits are cyclic shifted, interleaved and then mapped to QAM symbols.

In an example embodiment, each real spatial channel may be cyclic shifted by an amount that is the same or different than the amount of cyclic shifting done for other real spatial channels. In an example embodiment, an amount of cyclic shifting for the real spatial channels may linearly increase across the real spatial channels. For example, real spatial channel 1 may include a cyclic shift of zero bit positions (hence, the absence of a cyclic shifter in FIG. 9), real spatial channel 2 may cyclic shift bits by 5 bit positions (by cyclic shift 2 in FIG. 9), and real spatial channel 3 may cyclic shift bits by 10 bit positions (by cyclic shift 3 in FIG. 9). Thus, each successive real spatial channel may, for example, provide a linearly increasing amount of cyclic shifting. In this example, the amount of cyclic shifting increases by 5 bit positions, although any number may be used. The amount of cyclic shifting may be variable, e.g., under control of a controller not shown.

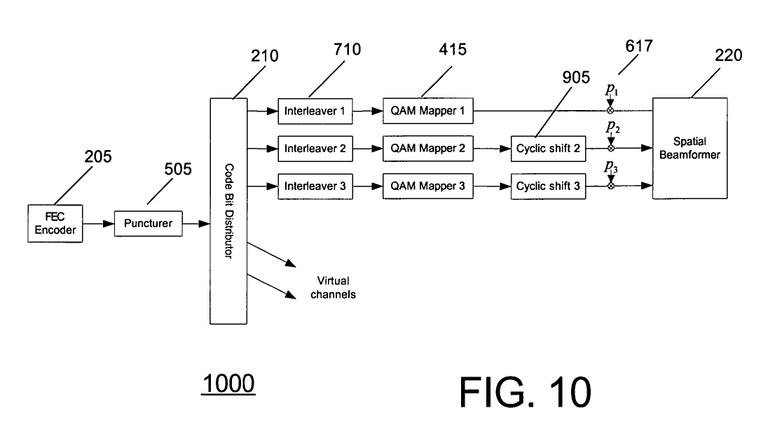

FIG. 10 is a block diagram of a wireless transmitter according to yet another example embodiment. Transmitter 1000 may be very similar to the transmitter 900 shown in FIG. 9, with some differences described below. Cyclic shifters 905 may be provided after QAM mappers 415 and before power adjustment 617. Therefore, in the example transmitter shown in FIG. 10, code bits are interleaved and mapped to QAM symbols. Cyclic shifters 905 may then perform a cyclic shifting of QAM symbols. Similar to the example above for FIG. 9, the amount of cyclic shifting of QAM symbols may linearly increase across the real spatial channels. E.g., spatial channel 0 may cyclic shift a group of symbols by 0 symbols (hence absence of cyclic shifter for channel 0), spatial channel 1 may cyclic shift a group of symbols by 4 symbols (cyclic shift 2) and real spatial channel 3 may cyclic shift a group of symbols by 8 symbols, although the invention is not limited thereto. The amount of cyclic shifting may be variable, e.g., under control of a controller not shown.

According to an example embodiment, for one or more of the transmitters shown in the Figures above, a different power loading or power adjustment can be added to each real spatial stream or each real spatial channel. For example, adjustable power loading may be provided for one or more of the real spatial channels. This may be referred to as power water-filling. In some embodiments, power water-filling may allow the transmitter to apply more transmission power on the good spatial channel and send more data through it (e.g., for those channels having higher quality or higher S/N ratio).

While certain features of the embodiments of the invention have been illustrated as described herein, many modifications, substitutions, changes and equivalents will now occur to those skilled in the art. It is, therefore, to be understood that the appended claims are intended to cover all such modifications and changes as fall within the true spirit of the embodiments of the invention.

What is claimed is:

1. An apparatus comprising:
an encoder to encode a plurality of data bits into a plurality of code bits;
a code bit distributor to assign or distribute at least some of the code bits to one or more real spatial channels for transmission and to distribute at least some code bits to one or more virtual spatial channels, the code bits distributed or assigned to the one or more virtual spatial channels to be discarded, punctured or transmitted at substantially zero power to effectively increase a code rate.

2. The apparatus of claim 1 wherein said encoder comprises a FEC encoder.

3. The apparatus of claim 1 wherein said encoder comprises a convolutional coder.

4. The apparatus of claim 1 wherein said encoder comprise a block coder.

5. The apparatus of claim 1 and further comprising a QAM mapper

6. The apparatus of claim 1 further comprising:
a symbol mapper coupled to the bit distributor to map coded bits to one of a plurality of symbols; and
a spatial beamformer coupled to the symbol mapper.

7. The apparatus of claim 1, and further comprising:
a puncturer to puncture one or more bits;
an interleaver to interleave one or more bits;
a symbol mapper coupled to the interleaver to map code bits to one or more modulation symbols; and
a spatial beamformer coupled to the symbol mapper.

8. The apparatus of claim 7 and further comprising a controller to adaptively control the code bit distributor to assign a selected number of bits to one or more of the virtual spatial channels based on a measured or received channel quality or other measurement or parameter.

9. The apparatus of claim 7 and further comprising a controller to adaptively control the symbol mapper to map code bits from one or more real spatial channels to symbols of a modulation scheme selected or specified by the controller, said modulation scheme being selected by the controller based on a measured or received channel quality or other measurement or parameter for each real spatial channel.

10. The apparatus of claim 7 and further comprising a controller to adaptively control two or more of the following:
a) a number of code bits to be distributed or assigned to a virtual channel to thereby increase a code rate;
b) a modulation scheme to be used for one or more real channels;
c) a number of bits, if any, to be punctured by the puncturer; and
d) amplitude and/or phase coefficients to be used the beamformer; and
e) a code rate to be used by the encoder to encode data bits.

11. The apparatus of claim 7 and further comprising a controller to adaptively control three or more of the following:
a) a number of code bits to be distributed or assigned to a virtual channel to thereby increase a code rate;
b) a modulation scheme to be used for one or more real channels;
c) a number of bits, if any, to be punctured by the puncturer; and
d) amplitude and/or phase coefficients to be used the beamformer;
e) a code rate to be used by the encoder to encode data bits; and
f) a number of power loadings to be used for one or more real channels.

12. The apparatus of claim 1 and further comprising an adaptive spatial beamformer.

13. A MIMO transmitter comprising:
an encoder to encode a plurality of data bits into a plurality of code bits;
a code bit distributor to distribute or assign at least some of the code bits to one or more real spatial channels for transmission and to distribute at least some of the code bits to one or more virtual spatial channels, the code bits distributed or assigned to the one or more of the virtual spatial channels to be discarded, punctured or transmitted at substantially zero power to effectively increase a code rate for the transmitter;
a symbol mapper to map code bits to one or more modulation symbols;
a spatial beamformer coupled to the symbol mapper; and
a controller, the controller to adaptively select a modulation scheme to be used by the symbol mapper to map symbols for each real channel or to control the symbol mapper to use a selected modulation scheme for each real spatial channel, wherein a different modulation scheme may be used for each real spatial channel.

14. The MIMO transmitter of claim 13 wherein the controller also adaptively controls the operation of the beamformer.

15. The MIMO transmitter of claim 13 and further comprising a puncturer to discard or puncture one or more bits.

16. The MIMO transmitter of claim 13 and wherein the controller also adaptively adjusts power loadings to be used for one or more real channels.

17. A method of increasing a code rate for a MIMO transmitter, the method comprising:
encoding one or more data bits into one or more code bits;
assigning at least some of the code bits to one or more real spatial channels for transmission; and
assigning at least some of the code bits to one or more virtual spatial channels, the code bits assigned to the one or more virtual spatial channels to be discarded, punctured or transmitted at substantially zero power to effectively increase a code rate for the transmitter.

18. The method of claim 17 and further comprising:
mapping one or more code bits for one or more real spatial channels to one or more modulation symbols; and
transmitting the symbols.

19. The method of claim 17 and further comprising beamforming an electromagnetic radiation output from the transmitter.

20. The method of claim 17 and further comprising:
puncturing one or more bits;
interleaving one or more code bits, either within a real spatial channel and/or between different real spatial channels or among all real and virtual channels;
mapping one or more code bits for one or more real spatial channels to one or more modulation symbols; and
spatial beamforming an electromagnetic radiation that is output.

21. The method of claim 20, further comprising selecting a modulation scheme to be used for each real spatial channel.

22. The method of claim 21 wherein two or more of the following are performed adaptively based on a channel condition or other measurement:
assigning at least some of the code bits to one or more virtual spatial channels;
puncturing one or more bits;
selecting a modulation scheme to be used for each real spatial channel;
mapping one or more code bits for one or more real spatial channels to one or more modulation symbols; and
spatial beamforming an electromagnetic radiation that is output.

23. The method of claim 21 wherein three or more of the following are performed adaptively based on a channel condition or other measurement:
assigning at least some of the code bits to one or more virtual spatial channels;
puncturing one or more bits;
selecting a modulation scheme to be used for each real spatial channel;
mapping one or more code bits for one or more real spatial channels to one or more modulation symbols;
spatial beamforming an electromagnetic radiation that is output; and
adjusting power loadings to be used for one or more real channels.

24. A wireless transmitter comprising:
an encoder to encode a plurality of data bits into a plurality of code bits;
a controller to select a number of virtual channels to be used, the number of virtual channels to be zero or more;
a code bit distributor to distribute or assign at least some of the code bits to one or more real channels for transmission;
if the selected number of virtual channels is one or more, the code bit distributor to distribute one or more of the code bits to the selected virtual channels, the code bits distributed or assigned to the virtual spatial channels to be discarded, punctured or transmitted at substantially zero power to effectively increase a code rate for the transmitter.

25. The transmitter of claim 24 and further comprising:
a symbol mapper to map code bits to one or more modulation symbols;
a spatial beamformer coupled to the symbol mapper; and
a controller, the controller to adaptively select a modulation scheme to be used by the symbol mapper to map symbols for each real channel or to control the symbol mapper to use a selected modulation scheme for each real spatial channel, wherein a different modulation scheme may be used for each real spatial channel.

26. The transmitter of claim 24 and further comprising:
one or more interleavers to interleave code bits; and
one or more cyclic shifters to perform cyclic shifting.

27. The transmitter of claim 26 wherein the one or more cyclic shifters perform a linearly increasing amount of cyclic shifting across a plurality of real channels.

28. The transmitter of claim 24 and further comprising:
one or more interleavers to interleave code bits;
one or more QAM mapper to map code bits to symbols; and
one or more cyclic shifters to perform cyclic shifting on symbols output from the one or more QAM mapper.
